(19) United States
(12) Patent Application Publication
(10) Pub. No.: US 2017/0166778 A1
(43) Pub. Date: Jun. 15, 2017

(54) CHEMICAL MECHANICAL POLISHING (CMP) COMPOSITION COMPRISING A POLY(AMINOACID)

(71) Applicant: BASF SE, Ludwigshafen (DE)

(72) Inventors: Michael LAUTER, Mannheim (DE); Roland LANGE, Limburgerhof (DE); Bastian Marten NOLLER, Neuhofen (DE); Max SIEBERT, Ludwigshafen (DE)

(73) Assignee: BASF SE, Ludwigshafen (DE)

(21) Appl. No.: 15/115,747

(22) PCT Filed: Jan. 21, 2015
(86) PCT No.: PCT/IB2015/050454

§ 371 Date: Aug. 1, 2016

(30) Foreign Application Priority Data
Jan. 31, 2014 (EP) 14153454.5

(51) Int. Cl. C09G 1/02; H01L 21/321; H01L 21/3105; C09K 3/14

(52) U.S. Cl. CPC C09G 1/02; C09K 3/1409; H01L 21/3212; H01L 21/31055

(57) ABSTRACT

A chemical mechanical polishing (CMP) composition comprising (A) Colloidal or fumed inorganic particles or a mixture thereof, (B) a poly (amino acid) and or a salt thereof, and (M) an aqueous medium.

This invention essentially relates to a chemical mechanical polishing (CMP) composition and its use in polishing substrates of the semiconductor industry. The CMP composition according to the invention comprises a poly (aminoacid) and shows an improved polishing performance.

In the semiconductor industry, chemical mechanical polishing (abbreviated as CMP) is a well-known technology applied in fabricating advanced photonic, microelectromechanical, and microelectronic materials and devices, such as semiconductor wafers.

During the fabrication of materials and devices used in the semiconductor industry, CMP is employed to planarize metal and/or oxide surfaces. CMP utilizes the interplay of chemical and mechanical action to achieve the planarity of the to-be-polished surfaces. Chemical action is provided by a chemical composition, also referred to as CMP composition or CMP slurry. Mechanical action is usually carried out by a polishing pad which is typically pressed onto the to-be-polished surface and mounted on a moving platen. The movement of the platen is usually linear, rotational or orbital.

In a typical CMP process step, a rotating wafer holder brings the to-be-polished wafer in contact with a polishing pad. The CMP composition is usually applied between the to-be-polished wafer and the polishing pad.

In the state of the art, CMP compositions comprising a poly (aminoacid) are known and described, for instance, in the following reference.

JP 2000-192015 A discloses a CMP polishing agent comprising cerium oxide particles, a dispersant, a biodegradable surfactant and water. One or more compounds selected from polymer dispersants, water-soluble anionic surfactants, water-soluble nonionic surfactants, water-soluble cationic surfactants and water-soluble ampholytic surfactants are used. Preferred examples of the biodegradable surfactant include—inter alia—
polyamino acids, such as poly (aspartic acid), poly (glutamic acid), poly (lysine), aspartic acid-glutamic acid copolymer, aspartic acid-lysine copolymer and glutamic acid-lysine copolymer, and derivatives thereof, as well as
polysaccharides such as starch, chitosan, algenic acid, carboxy methyl cellulose, methyl cellulose, pullulan, curdlan and derivatives thereof

One of the objects of the present invention was to provide a CMP composition appropriate for the CMP of surfaces of dielectric substrates in shallow trench isolation and showing an improved polishing performance, particularly a high selectivity for silicon dioxide over silicon nitride or polysilicon indicated by the combination of high material removal rate (MRR) of silicon dioxide and low MRR of silicon nitride or polysilicon. Furthermore, a CMP composition was sought that is dipersant free, storage stable and would be ready-to-use in acidic to alkalescent pH range.

Furthermore, a respective CMP process was to be provided.

Accordingly, a CMP composition was found which comprises
(A) Colloidal or fumed inorganic particles or a mixture thereof,
(B) a poly (aminoacid) and or a salt thereof, and
(M) an aqueous medium.

In addition, the above-mentioned objects of the invention are achieved by a process for the manufacture of a semiconductor device comprising the polishing of a substrate in the presence of said CMP composition.

Moreover, the use of the CMP composition of the invention for polishing substrates which are used in the semiconductor industry has been found, which fulfills the objects of the invention.

Preferred embodiments are explained in the claims and the specification. It is understood that combinations of preferred embodiments are within the scope of the present invention.

A semiconductor device can be manufactured by a process which comprises the CMP of a substrate in the presence of the CMP composition of the invention. Preferably, said process comprises the CMP of a dielectric substrate, that is a substrate having a dielectric constant of less than 6. Said process comprises more preferably the CMP of a substrate comprising silicon dioxide, most preferably the CMP of a substrate comprising silicon dioxide and silicon nitride or polysilicon, particularly the CMP of a silicon dioxide layer of a substrate which is a shallow trench isolation (STI) device or a part thereof, for example the CMP of a silicon dioxide layer of a substrate comprising silicon dioxide and silicon nitride or polysilicon.

If said process comprises the CMP of a substrate comprising silicon dioxide and silicon nitride, the selectivity of silicon dioxide to silicon nitride with regard to the material removal rate is preferably higher than 20:1, more preferably higher than 35:1, most preferably higher than 50:1, particularly higher than 70:1, for example higher than 90:1.

If said process comprises the CMP of a substrate comprising silicon dioxide and polysilicon, the selectivity of silicon dioxide to polysilicon with regard to the material removal rate is preferably higher than 50:1, more preferably higher than 80:1, most preferably higher than 100:1, particularly higher than 120:1, for example higher than 180:1.

Both the selectivity of silicon dioxide to silicon nitride as well as the selectivity of silicon dioxide to polysilicon can be adjusted by the type and concentration of poly (aminoacid) (B) and by the type of inorganic particles (A) and by setting other parameters such as pH value.

The CMP composition of the invention is used for polishing any substrate used in the semiconductor industry. Said CMP composition is used preferably for polishing a dielectric substrate, that is a substrate having a dielectric constant of less than 6, more preferably for polishing a substrate comprising silicon dioxide, most preferably for polishing a substrate comprising silicon dioxide and silicon nitride or polysilicon, particularly for polishing a silicon dioxide layer of a substrate which is a shallow trench isolation (STI) device or a part thereof, and for example for polishing a silicon dioxide layer of a substrate comprising silicon dioxide and silicon nitride or polysilicon.

If the CMP composition of the invention is used for polishing a substrate comprising silicon dioxide and silicon nitride, the selectivity of silicon dioxide to silicon nitride with regard to the material removal rate is preferably higher than 20:1, more preferably higher than 35:1, most preferably higher than 50:1, particularly higher than 70:1, for example higher than 90:1.

If the CMP composition of the invention is used for polishing a substrate comprising silicon dioxide and polysilicon, the selectivity of silicon dioxide to polysilicon with regard to the material removal rate is preferably higher than 50:1, more preferably higher than 80:1, most preferably higher than 100:1, particularly higher than 120:1, for example higher than 180:1.

According to the invention, the CMP composition comprises colloidal or fumed inorganic particles or a mixture thereof (A).

Generally, colloidal inorganic particles are inorganic particles which are produced by a wet precipitation process; fumed inorganic particles are produced by high temperature flame hydrolysis of for example metal chloride precursor with hydrogen in the presence of oxygen, for example using the Aerosil® process.

(A) can be
of one type of colloidal inorganic particles,
of one type of fumed inorganic particles,
a mixture of different types of colloidal and/or fumed inorganic particles,

Generally, the particles (A) can be contained in varying amounts. Preferably, the amount of (A) is not more than 10 wt. % (“wt. %” stands for “percent by weight”), more preferably not more than 5 wt. %, most preferably not more than 2 wt. %, for example not more than 0.75 wt. %, based on the total weight of the corresponding composition. Preferably, the amount of (A) is at least 0.005 wt. %, more preferably at least 0.01 wt. %, most preferably at least 0.05 wt. %, for example at least 0.1 wt. %, based on the total weight of the corresponding composition.

Generally, the particles (A) can be contained in varying particle size distributions. The particle size distributions of the particles (A) can be monomodal or multimodal. In case of multimodal particle size distributions, bimodal is often preferred. In order to have an easily reproducible property profile and easily reproducible conditions during the CMP process of the invention, a monomodal particle size distribution is preferred for (A). It is most preferred for (A) to have a monomodal particle size distribution.

The mean particle size of the particles (A) can vary within a wide range. The mean particle size is the d₅₀ value of the particle size distribution of (A) in the aqueous medium (M) and can be measured for example using dynamic light scattering (DLS) or static light scattering (SLS) methods. These and other methods are well known in the art, see e.g. Kuntzsch, Timo; Witnik, Ulrike; Hollatz, Michael Stintz; Ripperger, Siegfried; Characterization of Slurries Used for Chemical-Mechanical Polishing (CMP) in the Semiconductor Industry; Chem. Eng. Technol; 26 (2003), volume 12, page 1235.

For DLS, typically a Horiba LB-550 V (DLS, dynamic light scattering measurement according to manual) or any other such instrument is used. This technique measures the hydrodynamic diameter of the particles as they scatter a laser light source (λ=650 nm), detected at an angle of 90° or 173° to the incoming light. Variations in the intensity of the scattered light are due to the random Brownian motion of the particles as they move through the incident beam and are monitored as a function of time. Autocorrelation functions performed by the instrument as a function of delay time are used to extract decay constants; smaller particles move with higher velocity through the incident beam and correspond to faster decays.

These decay constants are proportional to the diffusion coefficient, Dₜ, of the particle and are used to calculate particle size according to the Stokes-Einstein equation:

$${D}_{k} = \frac{{k}_{B} T}{3 πη {D}_{t}}$$

where the suspended particles are assumed to (1) have a spherical morphology and (2) be uniformly dispersed (i.e. not agglomerated) throughout the aqueous medium (M). This relationship is expected to hold true for particle dispersions that contain lower than 1% by weight of solids as there are no significant deviations in the viscosity of the aqueous dispersant (M), in which η=0.96 mPa·s (at T=22° C.). The particle size distribution of the ceria dispersion (A) is usually measured in a plastic cuvette at 0.1 to 1.0% solid concentration and dilution, if necessary, is carried out with the dispersion medium or ultra-pure water.

Preferably, the mean particle size of the particles (A) is in the range of from 20 to 200 nm, more preferably in the range of from 25 to 180 nm, most preferably in the range of from 30 to 170 nm, particularly preferably in the range of from 40 to 160 nm, and in particular in the range of from 45 to 150 nm, as measured with dynamic light scattering techniques using instruments for example a High Performance Particle Sizer (HPPS) from Malvern Instruments, Ltd. or Horiba LB550.

The BET surface determined according to DIN ISO 9277:2010-09 of the particles (A) can vary within a wide range. Preferably, the BET surface of the particles (A) is in the range of from 1 to 500 m²/g, more preferably in the range of from 5 to 250 m²/g, most preferably in the range of from 10 to 100 m²/g, in particular in the range of from 20 to 90 m²/g, for example in the range of from 25 to 85 m²/g.

The particles (A) can be of various shapes. Thereby, the particles (A) may be of one or essentially only one type of shape. However, it is also possible that the particles (A) have different shapes. For instance, two types of differently shaped particles (A) may be present. For example, (A) can have the shape of cubes, cubes with bevelled edges, octahedrons, icosahedrons, cocoons, nodules or spheres with or without protrusions or indentations. Preferably, they are essentially spherical, whereby typically these have protrusions or indentations.

The chemical nature of particles (A) is not particularly limited. (A) may be of the same chemical nature or a mixture of particles of different chemical nature. As a rule, particles (A) of the same chemical nature are preferred. Generally, (A) can be
inorganic particles such as a metal, a metal oxide or carbide, including a metalloid, a metalloid oxide or carbide, or
a mixture of inorganic particles.

Particles (A) are colloidal or fumed inorganic particles or a mixture thereof. Among them, oxides and carbides of metals or metalloids are preferred. More preferably, particles (A) are alumina, ceria, copper oxide, iron oxide, nickel oxide, manganese oxide, silica, silicon nitride, silicon carbide, tin oxide, titania, titanium carbide, tungsten oxide, yttrium oxide, zirconia, or mixtures or composites thereof. Most preferably, particles (A) are alumina, ceria, silica, titania, zirconia, or mixtures or composites thereof. In particular, (A) are ceria. For example, (A) are colloidal ceria.

According to the invention, the CMP composition comprises
(B) a poly (aminoacid).

Generally, a poly (aminoacid) is a technically synthesized polycondensation product of predominantly α-amino acids, synthesized by polymerization of the respective N-carboxy-anhydrides or a naturally occurring polymer of amino acids as for example poly (glutamicacid). Poly (aminoacids) are commercially available for nearly all standard α-amino acids as homo polymer or as copolymer of different amino acids up to high molecular weights. In general polypeptides and proteins are not counted among the poly (aminoacids).

In general, any poly (aminoacid) (B) can be used.

According to the invention poly (aminoacid) (B) can be homo- or copolymer, abbreviated together also as poly (aminoacid) (B). The latter may for example be a block-copolymer, or statistical copolymer. The homo- or copolymer may have various structures, for instance linear, branched, comb-like, dendrimeric, entangled or cross-linked. Preferably, the poly (aminoacid) (B) is poly (aspartic acid), poly (glutamic acid), poly (lysine), aspartic acid-glutamic acid copolymer, aspartic acid-lysine copolymer, or glutamic acid-lysine copolymer, or a salt, or a mixture thereof, more preferably, (B) is poly (aspartic acid), poly (glutamic acid), poly (lysine) or a salt, or a mixture thereof, most preferably (B) is poly (aspartic acid), poly (glutamic acid) or a salt, or mixture thereof, particulary (B) is poly (aspartic acid) or a salt thereof, for example sodium polyaspartate.

In general the poly (aminoacid) can have a wide range of average molecular weight M_{w}. Preferably, the poly (aminoacid) (B) has an average molecular weight M_{w}in the range from 200 to 10000 g/mol, more preferably in the range from 400 to 6000 g/mol, most preferably in the range from 600 to 5000 g/mol, particularly preferably in the range from 800 to 4000 g/mol, determinable for example by gel permeation chromatography (GPC).

In general, the poly (aminoacid) (B) can be contained in varying amounts. Preferably, the amount of (B) is not more than 5 wt. %, more preferably not more than 1 wt. %, most preferably not more than 0.5 wt. %, particularly not more than 0.15 wt. %, for example not more than 0.08 wt. %, based on the total weight of the corresponding composition. Preferably, the amount of (B) is at least 0.0001 wt. %, more preferably at least 0.001 wt. %, most preferably at least 0.002 wt. %, particularly at least 0.006 wt. %, for example at least 0.01 wt. %, based on the total weight of the corresponding composition.

The CMP composition of the invention can further optionally contain at least one saccharide (C), for example one saccharide. According to the invention the saccharide may be a substituted derivative thereof, for example a halogen substituted derivative. The saccharide is no polysaccharide, which is a saccharide polymer containing more than ten monosaccharide units. Preferably, the saccharide is a mono-, di-, tri-, tetra-, penta-, hexa-, hepta-, octa-saccharides or a oxidized derivative, or a reduced derivative, or a substituted derivative, or a mixture thereof, more preferably the saccharide is glucose, galactose, saccharose or sucralose, or derivatives and stereoisomers, or a mixture thereof, most preferably the saccharide is galactose or sucralose, or derivatives and stereoisomers, or a mixture thereof, for example the saccharide is galactose.

If present, the saccharide (C) can be contained in varying amounts. Preferably, the amount of (C) is not more than 4 wt. %, more preferably not more than 1 wt. %, most preferably not more than 0.5 wt. %, for example not more than 0.25 wt. %, based on the total weight of the corresponding composition. Preferably, the amount of (C) is at least 0.005 wt. %, more preferably at least 0.01 wt. %, most preferably at least 0.05 wt. %, for example at least 0.08 wt. %, based on the total weight of the corresponding composition.

The CMP composition of the invention can further optionally contain at least one corrosion inhibitor (D), for example two corrosion inhibitors. Preferred corrosion inhibitors are diazoles, triazoles, tetrazoles and their derivatives, for example benzotriazole or tolyltriazole. Other examples for preferred corrosion inhibitors are acetylene alcohols, or a salt or an adduct of an amine and a carboxylic acid comprising an amide moiety.

If present, the corrosion inhibitor (D) can be contained in varying amounts. Preferably, the amount of (D) is not more than 10 wt. %, more preferably not more than 5 wt. %, most preferably not more than 2.5 wt. %, for example not more than 1.5 wt. %, based on the total weight of the corresponding composition. Preferably, the amount of (D) is at least 0.01 wt. %, more preferably at least 0.1 wt. %, most preferably at least 0.3 wt. %, for example at least 0.8 wt. %, based on the total weight of the corresponding composition.

The CMP composition of the invention can further optionally contain at least one oxidizing agent (E), for example one oxidizing agent. In general, the oxidizing agent is a compound which is capable of oxidizing the to-be-polished substrate or one of its layers. Preferably, (E) is a pertype oxidizer. More preferably, (E) is a peroxide, persulfate, perchlorate, perbromate, periodate, permanganate, or a derivative thereof. Most preferably, (E) is a peroxide or persulfate. Particularly, (E) is a peroxide. For example, (E) is hydrogen peroxide.

If present, the oxidizing agent (E) can be contained in varying amounts. Preferably, the amount of (E) is not more than 20 wt. %, more preferably not more than 10 wt. %, most preferably not more than 5 wt. %, for example not more than 2 wt. %, based on the total weight of the corresponding composition. Preferably, the amount of (E) is at least 0.05 wt. %, more preferably at least 0.1 wt. %, most preferably at least 0.5 wt. %, for example at least 1 wt. %, based on the total weight of the corresponding composition.

The CMP composition of the invention can further optionally contain at least one complexing agent (F), for example one complexing agent. In general, the complexing agent is a compound which is capable of complexing the ions of the to-be-polished substrate or of one of its layers. Preferably, (F) is a carboxylic acid having at least two COOH groups, an N-containing carboxylic acid, N-containing sulfonic acid, N-containing sulfuric acid, N-containing phosphonic acid, N-containing phosphoric acid, or a salt thereof. More preferably, (F) is a carboxylic acid having at least two COOH groups, an N-containing carboxylic acid, or a salt thereof. Most preferably, (F) is an amino acid, or a salt thereof. For example, (F) is glycine, serine, alanine, hystidine, or a salt thereof.

If present, the complexing agent (F) can be contained in varying amounts. Preferably, the amount of (F) is not more than 20 wt. %, more preferably not more than 10 wt. %, most preferably not more than 5 wt. %, for example not more than 2 wt. %, based on the total weight of the corresponding composition. Preferably, the amount of (F) is at least 0.05 wt. %, more preferably at least 0.1 wt. %, most preferably at least 0.5 wt. %, for example at least 1 wt. %, based on the total weight of the corresponding composition.

The CMP composition of the invention can further optionally contain at least one biocide (G), for example one biocide. In general, the biocide is a compound which deters, renders harmless, or exerts a controlling effect on any harmful organism by chemical or biological means. Preferably, (G) is an quaternary ammonium compound, an isothiazolinone-based compound, an N-substituted diazenium dioxide, or an N′-hydroxy-diazenium oxide salt. More preferably, (G) is an N-substituted diazenium dioxide, or an N′-hydroxy-diazenium oxide salt.

If present, the biocide (G) can be contained in varying amounts. If present, the amount of (G) is preferably not more than 0.5 wt. %, more preferably not more than 0.1 wt. %, most preferably not more than 0.05 wt. %, particularly not more than 0.02 wt. %, for example not more than 0.008 wt. %, based on the total weight of the corresponding composition. If present, the amount of (G) is preferably at least 0.0001 wt. %, more preferably at least 0.0005 wt. %, most preferably at least 0.001 wt. %, particularly at least 0.003 wt. %, for example at least 0.006 wt. %, based on the total weight of the corresponding composition.

According to the invention, the CMP composition contains an aqueous medium (M). (M) can be of one type or a mixture of different types of aqueous media.

In general, the aqueous medium (M) can be any medium which contains water. Preferably, the aqueous medium (M) is a mixture of water and an organic solvent miscible with water (e.g. an alcohol, preferably a C₁ to C₃ alcohol, or an alkylene glycol derivative). More preferably, the aqueous medium (M) is water. Most preferably, aqueous medium (M) is de-ionized water.

If the amounts of the components other than (M) are in total x % by weight of the CMP composition, then the amount of (M) is (100-x) % by weight of the CMP composition.

The properties of the CMP composition according to the invention respectively, such as stability and polishing performance, may depend on the pH of the corresponding composition. Preferably, the pH value of the compositions used or according to the invention respectively is in the range of from 3 to 11, more preferably from 3.5 to 9, most preferably from 3.8 to 8.5, particularly preferably from 4 to 8, for example from 4.2 to 7.8.

The CMP compositions according to the invention respectively may also contain, if necessary, various other additives, including but not limited to pH adjusting agents, stabilizers etc. Said other additives are for instance those commonly employed in CMP compositions and thus known to the person skilled in the art. Such addition can for example stabilize the dispersion, or improve the polishing performance, or the selectivity between different layers.

If present, said additive can be contained in varying amounts. Preferably, the amount of said additive is not more than 10 wt. %, more preferably not more than 1 wt. %, most preferably not more than 0.1 wt. %, for example not more than 0.01 wt. %, based on the total weight of the corresponding composition. Preferably, the amount of said additive is at least 0.0001 wt. %, more preferably at least 0.001 wt. %, most preferably at least 0.01 wt. %, for example at least 0.1 wt. %, based on the total weight of the corresponding composition.

Dispersant-free in the context of the present invention means, that the composition comprises no or less than 50 ppm of water soluble anionic-, water soluble non-ionic-, water soluble cationic- and water soluble ampholytic surfactants as for example polyacrylic acid, based on the total weight of the composition.

Examples of CMP compositions according to the invention

E1:
(A) fumed inorganic particles,
(B) a poly (aminoacid), and
(M) an aqueous medium.

E2:
(A) colloidal inorganic particles,
(B) a poly (aminoacid), and
(M) an aqueous medium.

E3:
(A) colloidal ceria particles in an amount of from 0.008 to 1.8 wt. %, based on the total weight of the corresponding CMP composition,
(B) a poly (aminoacid), and
(M) an aqueous medium.

E4:
(A) colloidal or fumed ceria particles or a mixture thereof, wherein the mean particle size of the ceria particles is from 20 nm to 200 nm, as determined by dynamic light scattering techniques
(B) poly (aspartic acid), poly (glutamic acid), poly (lysine), aspartic acid-glutamic acid co-polymer, aspartic acid-lysine copolymer, or glutamic acid-lysine copolymer, or a salt, or a mixture thereof,
(M) water.

E5:
(A) colloidal ceria particles in an amount of from 0.008 to 1.8 wt. %, based on the total weight of the corresponding CMP composition,
(B) poly (aspartic acid) in an amount of from 0.001 to 2.5 wt. %, based on the total weight of the corresponding CMP composition, and
(M) an aqueous medium.

E6:
(A) colloidal ceria particles in an amount of from 0.008 to 1.8 wt. %, based on the total weight of the corresponding CMP composition,
(B) poly (aspartic acid) in an amount of from 0.001 to 2.5 wt. %, based on the total weight of the corresponding CMP composition, and
(C) a saccharide
(M) an aqueous medium.

E7:
(A) colloidal or fumed ceria particles or a mixture thereof, wherein the mean particle size of the ceria particles is from 20 nm to 200 nm, as determined by dynamic light scattering techniques
(B) is poly (aspartic acid), poly (glutamic acid), poly (lysine), aspartic acid-glutamic acid copolymer, aspartic acid-lysine copolymer, or glutamic acid-lysine copolymer, or a salt, or a mixture thereof,
(C) a saccharide wherein (C) is a mono-, di-, tri-, tetra-, penta-, hexa-, hepta-, octasaccharides, or a oxidized derivative, or a reduced derivative, or a substituted derivative or a mixture thereof.
(M) is water

E8:
(A) colloidal ceria particles in an amount of from 0.008 to 1.8 wt. %, based on the total weight of the corresponding CMP composition, wherein the mean particle size of the particles (A) is from 35 nm to 180 nm, as determined by dynamic light scattering techniques
(B) poly (aspartic acid) in an amount of from 0.001 to 2.5 wt. %, based on the total weight of the corresponding CMP composition, and
(C) a saccharide in an amount of from 0.008 to 3 wt. %, based on the total weight of the corresponding CMP composition, and
(M) an aqueous medium.

Processes for preparing CMP compositions are generally known. These processes may be applied to the preparation of the CMP composition of the invention. This can be carried out by dispersing or dissolving the above-described components (A), (B) and optional components (C) to (G) in the aqueous medium (M), preferably water, and optionally by adjusting the pH value through adding an acid, a base, a buffer or a pH adjusting agent. For this purpose the customary and standard mixing processes and mixing apparatuses such as agitated vessels, high shear impellers, ultrasonic mixers, homogenizer nozzles or counterflow mixers, can be used.

The CMP composition of the invention is preferably prepared by dispersing the particles (A), dispersing and/or dissolving a poly (aminoacid) (B) and optionally further additives in the aqueous medium (M).

The polishing process is generally known and can be carried out with the processes and the equipment under the conditions customarily used for the CMP in the fabrication of wafers with integrated circuits. There is no restriction on the equipment with which the polishing process can be carried out.

As is known in the art, typical equipment for the CMP process consists of a rotating platen which is covered with a polishing pad. Also orbital polishers have been used. The wafer is mounted on a carrier or chuck. The side of the wafer being processed is facing the polishing pad (single side polishing process). A retaining ring secures the wafer in the horizontal position.

Below the carrier, the larger diameter platen is also generally horizontally positioned and presents a surface parallel to that of the wafer to be polished. The polishing pad on the platen contacts the wafer surface during the planarization process.

To produce material loss, the wafer is pressed onto the polishing pad. Both the carrier and the platen are usually caused to rotate around their respective shafts extending perpendicular from the carrier and the platen. The rotating carrier shaft may remain fixed in position relative to the rotating platen or may oscillate horizontally relative to the platen. The direction of rotation of the carrier is typically, though not necessarily, the same as that of the platen. The speeds of rotation for the carrier and the platen are generally, though not necessarily, set at different values. During the CMP process of the invention the CMP composition of the invention is usually applied onto the polishing pad as a continuous stream or in dropwise fashion. Customarily, the temperature of the platen is set at temperatures of from 10 to 70° C.

The load on the wafer can be applied by a flat plate made of steel for example, covered with a soft pad that is often called backing film. If more advanced equipment is being used a flexible membrane that is loaded with air or nitrogen pressure presses the wafer onto the pad. Such a membrane carrier is preferred for low down force processes when a hard polishing pad is used, because the down pressure distribution on the wafer is more uniform compared to that of a carrier with a hard platen design. Carriers with the option to control the pressure distribution on the wafer may also be used according to the invention. They are usually designed with a number of different chambers that can be loaded to a certain degree independently from each other.

For further details reference is made to WO 2004/063301 A1, in particular page 16, paragraph [0036] to page 18, paragraph [0040] in conjunction with the FIG. 2.

By way of the CMP process of the invention and/or using the CMP composition of the invention, wafers with integrated circuits comprising a dielectric layer can be obtained which have an excellent functionality.

The CMP composition of the invention can be used in the CMP process as ready-to-use slurry, they have a long shelf-life and show a stable particle size distribution over long time. Thus, they are easy to handle and to store. They show an excellent polishing performance, particularly with regard to the combination of high material removal rate (MRR) of silicon dioxide and low MRR of silicon nitride or polysilicon. Since the amounts of its components are held down to a minimum, the CMP composition according to the invention respectively can be used in a cost-effective way.

### EXAMPLES AND COMPARATIVE EXAMPLES

The general procedure for the CMP experiments is described below.

Standard CMP process for 200 mm SiO₂ wafers:

Strasbaugh nSpire (Model 6EC), ViPRR floating retaining ring Carrier;

down pressure: 2.0 psi (138 mbar);

back side pressure: 0.5 psi (34.5 mbar);

retaining ring pressure: 2.5 psi (172 mbar);

polishing table/carrier speed: 95/86 rpm;

slurry flow rate: 200 ml/min;

polishing time: 60 s;

pad conditioning: in situ, 4.0 lbs (18 N);

polishing pad: IC1000 A2 on Suba 4 stacked pad, xy, k, or k grooved (R&H);

backing film: Strasbaugh, DF200 (136 holes);

conditioning disk: 3M S60;

The pad is conditioned by three sweeps, before a new type of slurry is used for CMP.

The slurry is stirred in the local supply station.

Standard analysis procedure for (semi) transparent blanket wafers:

The removal is determined by optical film thickness measurement using Filmmetrics F50. 49 points diameter scans (5 mm edge exclusion) are measured pre and post CMP for each wafer. For each point on the wafer that was measured with F50 the film thickness loss is calculated from the difference of the film thickness pre and post CMP The average of the resulting data from the 49 point diameter scans gives the total removal, the standard deviation gives the (non-) uniformity.

For the removal rate the quotient of the total material removal and the time of the main polishing step is used.

Standard films used for CMP experiments:

SiO₂ films: PE TEOS;

Si₃N₄ films: PE CVD or LPCVD

Poly Si films: doped;

Standard procedure for slurry preparation:

An aqueous solution of poly (aspartic acid) salt is prepared. To this solution colloidal ceria particles (30% stock solution) are added under stirring. An aqueous solution of the saccharide, galactose or sucralose (10% stock solution), is added.

The pH is adjusted by adding of aqueous ammonia solution (0.1%) or HNO₃ (0.1%) to the slurry. The pH value is measured with a pH combination electrode (Schott, blue line 22 pH). Balance water may be added to adjust concentration.

Inorganic Particles (A) used in the Examples

Colloidal ceria particles having a mean primary particle size of 60 nm (as determined using BET surface area measurements) and having a mean secondary particle size (d50 value) of 99 nm (as determined using dynamic light scattering techniques via a Horiba instrument) (for example Rhodia HC60) were used.

Sodium salt of poly (aspartic acid) having a molecular weight of from 2000 to 3000 g/mol was used, it is commercially available for example as Baypure® DS 100 from Lanxess.

TABLE 1
CMP compositions of example 1 to 7 and of the comparative examples V1 to V4, their
pH values as well as their MRR (material removal rate) and selectivity data in the CMP
process using these compositions, wherein the aqueous medium (M) is de-ionized
water (wt. % = percent by weight; polySi = polysilicon)

| | | | | | | Selec- | Selec- |
|---|---|---|---|---|---|---|---|
| | | | | | | tivity | tivity |
| | | | MR | MRR | MRR | SiO₂/ | SiO₂/ |
| Ex- | Formulation of the | pH | SiO₂ | Si₃N₄ | poly Si | Si₃N₄ | poly Si |
| ample | composition | [ ] | [A/min] | [A/min] | [A/min] | [ ] | [ ] |
| Comp. | 0.1 wt. % (A) | 5.5 | 1870 | 153 | 76 | 12 | 24 |
| Ex V1 | colloidal ceria particles | | | | | | |
| Comp. | 0.5 wt. % (A) | 5.5 | 5259 | 494 | 367 | 11 | 14 |
| Ex V2 | colloidal ceria particles | | | | | | |
| Comp. | 0.1 wt. % (A) | 7 | Dispersion | — | — | — | — |
| Ex V3 | colloidal ceria particles | | not stable | | | | |
| Comp. | 0.5 wt. % (A) | 7 | Dispersion | — | — | — | — |
| Ex V4 | colloidal ceria particles | | not stable | | | | |
| Ex 1 | 0.1 wt. % (A) | 7 | 2374 | 42 | 21 | 57 | 113 |
| | colloidal ceria particles | | | | | | |
| | Polyaspartic acid (B) | | | | | | |
| | 0.002 wt. % | | | | | | |
| Ex 2 | 0.1 wt. % (A) | 7 | 1583 | 38 | 7 | 42 | 226 |
| | colloidal ceria particles | | | | | | |
| | Polyaspartic acid (B) | | | | | | |
| | 0.01 wt. % | | | | | | |
| Ex 3 | 0.5 wt. % (A) | 7 | 3689 | 52 | 16 | 71 | 231 |
| | colloidal ceria particles | | | | | | |
| | Polyaspartic acid (B) | | | | | | |
| | 0.01 wt. % | | | | | | |
| Ex 4 | 0.1 wt. % (A) | 7 | 1925 | 20 | 11 | 96 | 175 |
| | colloidal ceria particles | | | | | | |
| | Polyaspartic acid (B) | | | | | | |
| | 0.005 wt. % | | | | | | |
| | Galactose(C) 0.25 wt. % | | | | | | |
| Ex 5 | 0.1 wt. % (A) | 7 | 2053 | 18 | 10 | 114 | 205 |
| | colloidal ceria particles | | | | | | |
| | Polyaspartic acid (B) | | | | | | |
| | 0.01 wt. % | | | | | | |
| | Galactose(C) 0.25 wt. % | | | | | | |
| Ex 6 | 0.1 wt. % (A) | 7 | 1773 | 25 | 12 | 71 | 148 |
| | colloidal ceria particles | | | | | | |
| | Polyaspartic acid (B) | | | | | | |
| | 0.01 wt. % | | | | | | |
| | Galactose(C) 0.5 wt. % | | | | | | |
| Ex 7 | 0.1 wt. % (A) | 7 | 1845 | 25 | 10 | 74 | 185 |
| | colloidal ceria particles | | | | | | |
| | Polyaspartic acid (B) | | | | | | |
| | 0.01 wt. % | | | | | | |
| | Sucralose(C) 0.25 wt. % | | | | | | |

The CMP compositions of the examples 1 to 7 according to the invention are showing improved performance, in terms of dispersion stability, silicon oxide to silicon nitride selectivity and silicon oxide to polysilicon selectivity. The selectivity can be increased by up to a factor of 16 for silicon oxide to polysilicon selectivity and up to a factor of 10 for silicon oxide to silicon nitride selectivity by using CMP compositions according to the invention. By varying the amount of the compounds (B) and (C) the selectivity can be tuned within a wide range.

1. A chemical mechanical polishing (CMP) composition, comprising:
(A) Colloidal or fumed inorganic particles or a mixture thereof,
(B) a poly(amino acid) and or a salt thereof,
(C) a saccharide, and
(M) an aqueous medium,

2. The CMP composition according to claim 1, wherein the inorganic particles (A) are colloidal particles.

3. The CMP composition according to claim 1, wherein the inorganic particles (A) are fumed particles.

4. The CMP composition according to claim 1, wherein the inorganic particles (A) are ceria particles.

5. The CMP composition according to claim 1, wherein the mean particle size of the particles (A) is from 20 nm to 200 nm, as determined by dynamic light scattering techniques.

6. The CMP composition according to claim 1, wherein the poly (amino acid) (B) is poly (aspartic acid), poly (glutamic acid), poly (lysine), aspartic acid-glutamic acid copolymer, aspartic acid-lysine copolymer, or glutamic acid-lysine copolymer, or a salt, or a mixture thereof.

7. The CMP composition according to claim 1, wherein the poly (amino acid) (B) is poly (aspartic acid) and or a salt thereof.

8. (canceled).

9. The CMP composition according to claim 1, wherein the saccharide (C) is a mono-, di-, tri-, tetra-, penta-, hexa-, hepta-, octasaccharide, or a oxidized derivative, or a reduced derivative, or a substituted derivative or a mixture thereof.

10. The CMP composition according to claim 1, wherein the saccharide (C) is glucose, galactose, saccharose, or sucralose, or a derivative and a stereoisomer thereof, or a mixture thereof.

11. The CMP composition according to claim 1, wherein the pH value of the composition is in the range of from 4 to 9.

12. A process for the manufacture of semiconductor devices, the process comprising:
chemical mechanical polishing of a substrate with a CMP composition according to claim 1.

13. (canceled).

14. The method according to claim 12, wherein the substrate comprises:
(i) silicon dioxide, and
(ii) silicon nitride, or polvsilicon.
